(19) United States
(12) Patent Application Publication
(10) Pub. No.: US 2009/0107701 A1
(43) Pub. Date: Apr. 30, 2009

(54) PRINTED CIRCUIT BOARD HAVING ADHESIVE LAYER AND SEMICONDUCTOR PACKAGE USING THE SAME

(75) Inventors: Sung-Kyu PARK, Gyeonggi-do (KR); In-Ku KANG, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 12/145,770

(22) Filed: Jun. 25, 2008

(30) Foreign Application Priority Data
Oct. 24, 2007 (KR) 2007-0107418

(51) Int. Cl. H05K 1/09; H05K 1/16

(52) U.S. Cl. 174/251; 174/260

(57) ABSTRACT

A PCB having an adhesive layer and a semiconductor package using the same. The PCB includes a body substrate, a solder resist layer including an open portion that exposes a portion of the body substrate, and an adhesive layer formed on the body substrate in the open portion. The adhesive layer may include a solid die attach film or a liquid adhesive. A semiconductor chip may be attached to the adhesive layer. The semiconductor chip and the PCB may be molded by an encapsulant, thereby substantially covering the semiconductor chip and the PCB with the encapsulant.

### CROSS-REFERENCE TO RELATED PATENT APPLICATION

This application claims the benefit of Korean Patent Application No. 10-2007-0107418, filed on Oct. 24, 2007, in the Korean Intellectual Property Office, the disclosure of which is incorporated herein in its entirety by reference.

### BACKGROUND OF THE INVENTION

1. Field of the Invention

The present invention relates to a printed circuit board (PCB) and a semiconductor package using the same, and more particularly, to a PCB to which a semiconductor chip can be reliably attached and a semiconductor package using the same.

2. Description of the Related Art

Generally, since a semiconductor package may include a high density circuit as well as a semiconductor chip, the circuit and chip need to be protected from external environments. To this end, a semiconductor package may be fabricated by attaching a semiconductor chip on a PCB having a circuit pattern, connecting the semiconductor chip with the PCB by means of a wire or a bump, and performing a molding process by means of an encapsulant such as a resin.

As a result of an increase in performance and portability of electronic devices, semiconductor packages used in these electric devices need to be lighter, smaller, and thinner. To reduce the overall thickness of the semiconductor package, the thickness of a semiconductor chip needs to be reduced. However, reducing the thickness of the semiconductor chip can be difficult. Therefore, a need remains for improved methods of reducing the thickness.

Furthermore, when fabricating a semiconductor package, adhesiveness between a PCB and a semiconductor chip may be enhanced. Also, when fabricating a semiconductor package, it is important to reduce the number of packaging processes. If adhesiveness between a PCB and a semiconductor deteriorates, reliability of a semiconductor package correspondingly decreases. As a result, a need remains for improving adhesive reliability between a PCB and a semiconductor chip when fabricating a semiconductor package.

### SUMMARY OF THE INVENTION

The present invention provides a PCB capable of improving adhesive reliability between the PCB and a semiconductor chip.

The present invention also provides a semiconductor package having a thin thickness as a whole and an enhanced adhesive reliability between the semiconductor package and a semiconductor chip by using the aforementioned PCB.

According to an aspect of the present invention, there is provided a printed circuit board including: a body substrate; a solder resist layer including an open portion that exposes a portion of the body substrate, the solder resist layer having first and second ends adjacent to the open portion; and an adhesive layer formed on the body substrate in the open portion, the adhesive layer having first and second ends substantially adjacent to the first and second ends of the solder resist layer, respectively. The adhesive layer may include a solid die attach film or a liquid adhesive.

A width of the adhesive layer may be less than a width of the open portion so that the first and second ends of the adhesive layer are spaced apart from the first and second ends of the solder resist layer, respectively. Edge open portions exposing the body substrate may be formed at the first and second ends of the adhesive layer so that delamination of the adhesive layer is structurally suppressed due to a locking effect caused by the edge open portions.

The printed circuit board may further include a plurality of wiring patterns on a top surface of the body substrate and in the open portion. The adhesive layer may be formed on the wiring patterns and the body substrate in the open portion. The wiring patterns may be spaced apart from each other, wherein the adhesive layer is formed between the spaced apart wiring patterns and on the body substrate in the open portion, and wherein the adhesive layer and the wiring patterns are densely formed without voids.

The adhesive layer may be entirely formed on the body substrate in the open portion and between the separated wiring patterns, such that delamination is structurally suppressed by a locking effect. The open portion may be formed on a middle portion of the body substrate, and the solder resist layer may be formed on the body substrate around the open portion. The adhesive layer may have a top surface higher than the solder resist layer, and may have a substantially flat surface.

According to another aspect of the present invention, there is provided a semiconductor package including: a printed circuit board including a body substrate, a solder resist layer, and an adhesive layer, the solder resist layer including an open portion that exposes a portion of the body substrate, the solder resist layer having first and second ends adjacent to the open portion, the adhesive layer being formed on the body substrate in the open portion, the adhesive layer having first and second ends substantially adjacent to the first and second ends of the solder resist layer, respectively; a semiconductor chip formed on the adhesive layer of the printed circuit board; and an encapsulant structured to mold the printed circuit board and the semiconductor chip, thereby substantially covering the printed circuit board and the semiconductor chip with the encapsulant. The adhesive layer may include a solid die attach film or a liquid adhesive.

A width of the adhesive layer may be configured to be different from or less than a width of the semiconductor chip so that delamination of the adhesive layer and the semiconductor chip is structurally suppressed by a locking effect.

### BRIEF DESCRIPTION OF THE DRAWINGS

The above and other features and advantages of the present invention will become more apparent by describing in detail exemplary embodiments thereof with reference to the attached drawings in which:

FIG. 1 is a sectional view of a PCB according to an embodiment of the present invention;

FIG. 2 is a sectional view of a PCB of a comparative example for comparison with that of FIG. 1;

FIGS. 3 through 6 are sectional views for illustrating a method of fabricating a PCB according to an embodiment of the present invention;

FIG. 7 is a sectional view for illustrating a method of forming a PCB according to another embodiment of the present invention;

FIGS. 8 and 9 are sectional views of a semiconductor package according to embodiments of the present invention;

FIG. 10 is a sectional view of a semiconductor package of a comparative example for comparison with that of FIG. 9;

FIG. 11 is an enlarged view of one-sided portion of FIG. 9, which includes an encapsulant; and

FIG. 12 is a sectional view illustrating a finally completed semiconductor package according to an embodiment of the present invention.

### DETAILED DESCRIPTION OF THE INVENTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the thicknesses of layers and regions are exaggerated for clarity. It will also be understood that when a layer is referred to as being “on” another layer or substrate, it can be directly on the other layer or substrate, or intervening layers may also be present. Like reference numerals in the drawings denote like elements, and thus their description will be omitted.

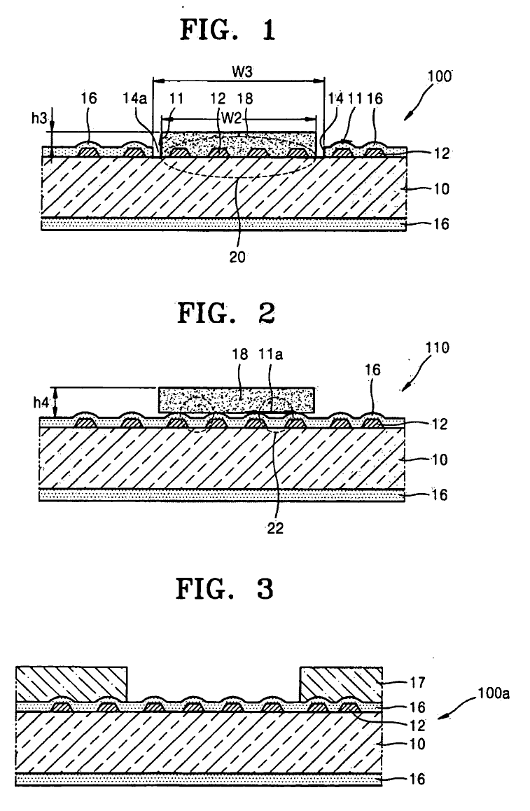

FIG. 1 is a sectional view of a printed circuit board (PCB) according to an embodiment of the present invention. Specifically, FIG. 1 illustrates only a portion of a cutting plane of a PCB 100 having a relatively wide area, for convenience. That is, the PCB 100 of FIG. 1, which will be described later, is a one cutting plane on which one semiconductor chip (not shown) will be attached. The PCB 100 includes a plurality of wiring patterns 12 on a body substrate 10. The wiring patterns 12 of FIG. 1 are illustrated as being formed on the top surface of the body substrate 10, but may be formed on the rear surface of the body substrate 10.

A part of the wiring patterns 12 may be formed on the top surface of the body substrate 10, and a solder resist layer 16 may be formed. The solder resist layer 16 may include an open portion 14, having a width (or length) of W3, which may expose a part of the body substrate 10. The wiring patterns 12 may or may not be formed in the open portion 14. The open portion 14 may be formed on the wiring patterns 12 in the middle portion of the body substrate 10, i.e., the middle portion of the top surface of the body substrate 10.

The solder resist layer 16 may be formed on the wiring patterns 12 and the body substrate 10 around the open portion 14. The wiring patterns 12 in the open portion 14 may be spaced apart from each other on the body substrate 10. The solder resist layer 16 is formed for the insulation between the wiring patterns 12. The solder resist layer 16 may also be formed on the bottom surface of the body substrate 10. The wiring patterns may also be formed (not shown) in the body substrate 10.

An adhesive layer 18 may be formed on the wiring patterns 12 and the body substrate 10 in the open portion 14. When forming the adhesive layer 18 in the open portion 14, adhesive reliability between the body substrate 10 and the adhesive layer 18 can be enhanced. The adhesive layer 18 is where a semiconductor chip is attached, and can be integrated in one body together with the PCB 100. That is, the adhesive layer 18 can be included when the PCB 100 is manufactured. The adhesive layer 18 may include a solid die attach film or a liquid adhesive.

The die attach film is used for attaching a die, i.e., a semiconductor chip. The attach film includes a polyimide base layer and an adhesive on the top and bottom surfaces of the polyimide base layer. The liquid adhesives may include an epoxy adhesive (e.g., Ag epoxy) for attaching a semiconductor chip.

A width W2 of the adhesive layer 18 may be less than the width W3 of the open portion 14. Accordingly, the ends of the adhesive layer 18 are spaced apart from the ends of the solder resist layer 16. Specifically, both ends of the adhesive layer 18 may be respectively spaced apart from one end of the solder resist area 16. The open portion 14 may include an edge open portion 14a exposing the body substrate 10. The edge open portion 14a may be exposed when forming the adhesive layer 18.

The adhesive layer 18 can structurally prevent delamination due to a locking effect caused by the edge open portion 14a. Conventionally, when the adhesive layer 18 is damaged or moisture penetrates through the adhesive layer 18, delamination occurs along a delamination propagation path. However, the PCB of the present invention lengthens a delamination propagation path 11 by means of the edge open portion 14a, such that a locking effect occurs. That is, because the delamination propagation path 11 is curved due to the edge open portion 14a, the delamination propagation path 11 lengthens. Accordingly, the PCB 100 of the present invention prevents the adhesive layer 18 from being delaminated, such that adhesive reliability between the adhesive layer 18 and the body substrate 10 is greatly improved.

The wiring patterns 12 may be spaced apart from each other in the open portion 14. The adhesive layer 18 may be formed between the wiring patterns 12 and on the body substrate 10 in the open portion 14. As shown in a portion indicated by a dotted line 20, there is no void between the adhesive layer 18 and the wiring patterns 12 in the open portion 14.

The adhesive layer 18 is generally formed between the wiring patterns 12, which are spaced apart from each other in the open portion 14, and on the body substrate 10 in the open portion 14. Because the adhesive layer 18 is formed between the wiring patterns 12 in the open portion 14, the above-mentioned delamination propagation path lengthens. Therefore, delamination of the adhesive layer 18 structurally is prevented by the locking effect.

The surface of the adhesive layer 18 where a semiconductor chip is attached is substantially flat. The top surface of the adhesive layer 18 is formed higher than the top surface of the solder resist layer 16. Accordingly, a semiconductor chip may be easily attached on the adhesive layer 18.

FIG. 2 is a sectional view of a PCB of a comparative example for comparison with that of FIG. 1. As illustrated in FIG. 2, like reference numerals denote like elements. The PCB 110 of FIG. 2 for comparison with that of FIG. 1 includes a plurality of separated wiring patterns 12 on the top surface of the body substrate 10, and a curved solder resist layer 16 on the wiring patterns 12. An adhesive layer 18 may be directly formed on the curved solder resist layer 16. Accordingly, a void 22 is formed between the adhesive layer 18 and the wiring patterns 12.

When there is a void between the adhesive layer 18 and the wiring patterns 12, a lattice between the adhesive layer 18 and the wiring patterns 12 is not dense, such that delamination very easily occurs. For example, a delamination propagation path 11a in the direction indicated by an arrow is simple and short, such that delamination very easily occurs.

Furthermore, the distance h4 from the top surface of the solder resist layer 16 to the top surface of the adhesive layer 18 is greater than the distance h3 of FIG. 1. Because the adhesive layer 18 of FIG. 1 is formed in the open portion 14, the distance from the top surface of the solder resist layer 16 to the top surface of the adhesive layer 18 of FIG. 1 is less than the distance h4 of FIG. 2.

Accordingly, the PCB 100 including the adhesive layer 18 in FIG. 1 can reduce the overall thickness compared to the PCB 110 in FIG. 2. If the entire thickness of the PCB 100 including the adhesive layer 18 is reduced, the thickness of a semiconductor package can be reduced.

FIGS. 3 through 6 are sectional views illustrating a method of forming a PCB according to an embodiment of the present invention.

Referring to FIG. 3, a PCB 100a is prepared for raw material including wiring patterns 12 on the top surface of the body substrate 10, and a solder resist layer 16 on the top surface and the bottom surface of the body substrate 10. Referring to FIG. 3, wiring patterns (not shown) may be disposed on the bottom surface of the body substrate 10. A solder mask layer 17 is formed by performing a photolithography process on the solder resist layer 16 at the top surface of the body substrate 10. Because of the solder mask layer 17, the surface of the solder resist layer 16 in the middle of the body substrate 10 is exposed by the solder mask layer 17.

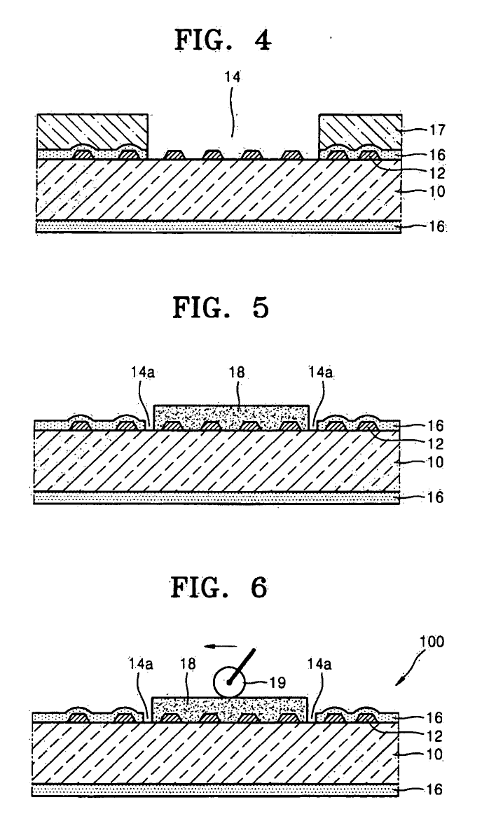

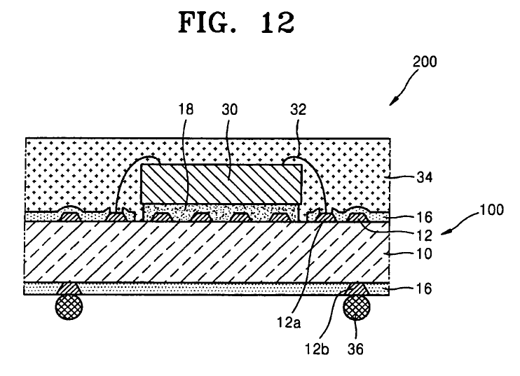

Referring to FIG. 4, using the solder mask layer 17 as a mask, the solder resist layer 16 is etched to form an open portion 14 that expose the wiring patterns 12 and the body substrate 10. The open portion 14 can be formed when performing a photolithography process to expose a bonding finger (e.g., a wiring pattern for a bond finger 12a of FIG. 12) while forming a conventional PCB, such that an additional forming process is not necessary. Although the wiring patterns 12 are formed in the open portion 14, the wiring patterns 12 need not be formed in a case where there is no wiring pattern while forming a PCB for raw material.

Referring to FIGS. 5 and 6, the solder mask layer 17 is removed. Next, an adhesive layer 18 is formed on the body substrate 10 within the open portion 14, including gaps between the wiring patterns 12 spaced apart from each other in the open portion 14. The adhesive layer 18 may be formed of a solid die attach film. After attaching the adhesive layer 18 in the open portion 14, it is thermally pressured on the body substrate 10 and the wiring pattern 12 by using a roller 19 under the conditions of an appropriate temperature and pressure. This rolling process reliably allows the adhesive layer 18 to be attached on the body substrate 10 without voids.

The adhesive layer 18 is formed between the spaced wiring patterns 12 and on the body substrate 10. Because the adhesive layer 18 is formed using the roller, there is almost no void between the adhesive layer 18 and the wiring patterns 12. The width of the adhesive layer 18 is less than that of the open portion. When forming the adhesive layer 18, an edge open portion 14a is formed at the both ends of the adhesive layer 18. Through the above forming processes, the PCB 100 is completed.

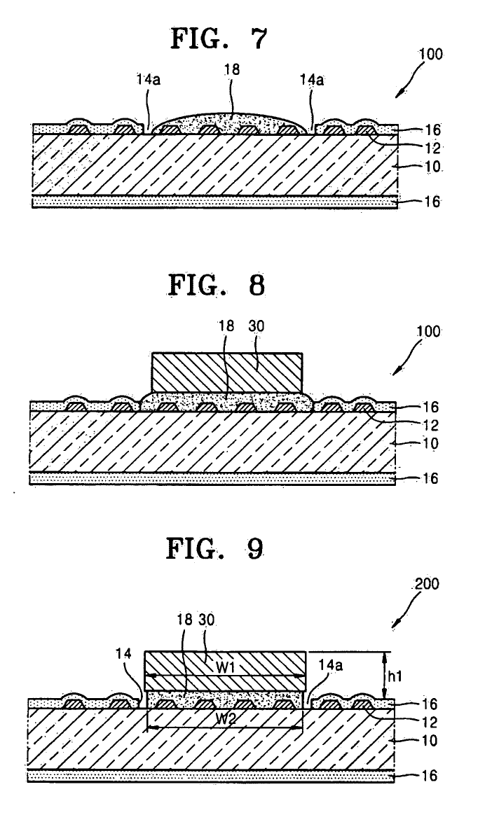

FIG. 7 is a sectional view illustrating a method of forming a PCB according to an embodiment of the present invention. Specifically, by using the same processes of FIGS. 3 and 4, an open portion 14 is formed on a PCB 100a for a raw material. Next, an adhesive layer 18 is formed in the open portion 14. The adhesive layer 18 is formed by applying epoxy adhesives (e.g., Ag epoxy). As illustrated in FIG. 7, because the adhesive layer 18 is formed to have the width less than the width of the open portion 14, an edge open portion 14a is formed at the both ends of the adhesive layer 18. Through these forming processes, the PCB 100 is completed.

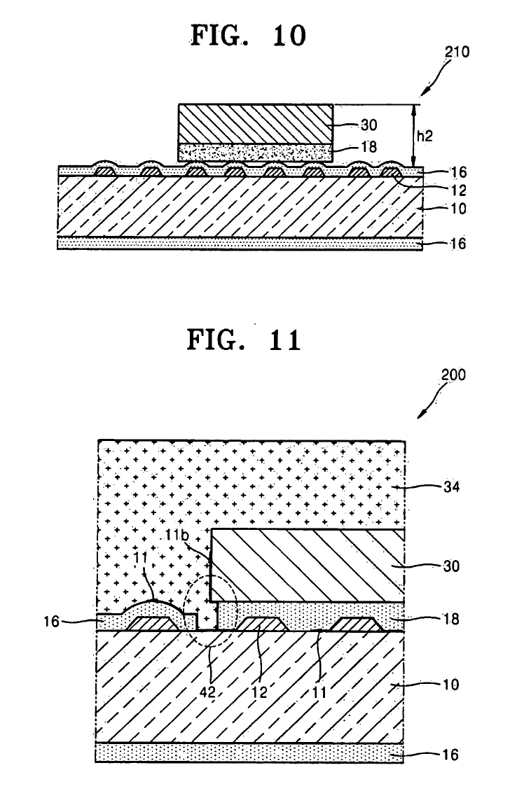

FIGS. 8 and 9 are sectional views of a semiconductor package according to embodiments of the present invention. FIG. 10 is a sectional view of a semiconductor package for comparison with that of FIG. 9. FIG. 11 is an enlarged view of one sectional view of FIG. 9, which includes an encapsulant 34.

Specifically, FIG. 8 illustrates a semiconductor chip 30 attached on the PCB 100 of FIG. 7. That is, as illustrated in FIG. 8, the adhesive layer 18 is filled in the open portion 14 by attaching the semiconductor chip 30 on the PCB 100. With this structure, the adhesive layer 18 may completely contact the body substrate 10, such that adhesive reliability between the body substrate 10 and the adhesive layer 18 can be greatly improved. Alternatively, the adhesive layer 18 may not completely fill the open portion 14 of the body substrate 14.

FIG. 9 illustrates the semiconductor chip 30 attached on the PCB 100 of FIG. 6. Referring to FIG.9, although the semiconductor chip 30 is attached, the adhesive layer 18 is not completely filled in the open portion 14 and the edge open portion 14a remains.

As previously explained, because the width of the adhesive layer 18 is less than the width of the open portion 14, an edge open portion 14a is formed at the both ends of the adhesive layer 18 when the adhesive layer 18 is formed. As illustrated in FIG. 11, due to the edge open portion, a delamination propagation path 42 lengthens, such that delamination of the adhesive layer 18 and the semiconductor chip 30 can be structurally suppressed because of a locking effect.

The semiconductor package 200 of FIG. 9 has a width W2 of the adhesive layer 18 different from the width W1 of the semiconductor chip 30. As indicated by the dotted line 42 of FIG. 11, a delamination propagation path 11b in a perpendicular direction lengthens, such that delamination of the adhesive layer 18 and the semiconductor chip 30 can be structurally suppressed because of the locking effect.

For example, referring to FIG. 9, the width W2 of the adhesive layer 18 is configured to be less than the width W1 of the semiconductor chip 30. The adhesive layer 18 of FIG. 9 lengthens a perpendicular delamination propagation path 11 of FIG. 11 between the wiring patterns 12 and on the body substrate 10 in the open portion, such that delamination of the adhesive layer 18 and the semiconductor layer 30 can be structurally suppressed because of the locking effect. Because the semiconductor package 200 of FIG. 9 utilizes the PCB 100 of FIG. 1, the locking effect using the PCB 100 of FIG. 1 is present.

In the semiconductor package 200 of FIG. 9, the distance h1 from the top surface of the solder resist layer 16 to the semiconductor chip is less than the distance h2 of FIG. 10. The reason is that the height of the solder resist layer 16 is reduced because the adhesive layer 18 of FIG. 9 is formed in the open portion 14. Accordingly, the semiconductor package 200 of the present invention may have a thinner thickness than the semiconductor package 210 of FIG. 10, such that it may be manufactured thinner than before.

FIG. 12 is a sectional view illustrating a finally completed semiconductor package according to an embodiment of the present invention. In more detail, the semiconductor chip 30 of the semiconductor package 200 of FIG. 12 may be wire bonded with a bonding finger 12a of the PCB 100, and the PCB 100 and semiconductor chip 30 may be molded with the encapsulant 34, thereby substantially covering the PCB 100 and semiconductor chip 30 with the encapsulant 34. The bottom surface of the body substrate 10 may include an exposed ball land 12b to which a solder ball 36 is attached.

The solder ball 36 may be attached to the ball land 12b. The semiconductor package 200 of FIG. 12 includes a single story semiconductor chip 30, but may have multi-story semiconductor chips. Additionally, FIG. 12 illustrates only a one semiconductor package among potentially several semiconductor packages on the PCB 100.

The PCB of the present invention includes the open portion that is formed by performing the photolithography process on the solder resist layer of the body substrate, and forms the adhesive layer in the open portion. Accordingly, the PCB of the present invention can greatly improve adhesive reliability between the adhesive layer and the body substrate.

The PCB of the present invention can achieve a locking effect by lengthening the delamination propagation path when the adhesive layer having less width than the open portion is formed with the edge open parts at both ends of the open portion. Accordingly, the PCB of the present invention can prevent delamination of the adhesive layer because of the locking effect.

Further, because the PCB of the present invention forms the adhesive layer in the open portion, the thickness of the PCB including the adhesive layer 18 can be reduced.

Moreover, the semiconductor package of the present invention is formed by attaching the semiconductor chip on the adhesive layer of the PCB. Accordingly, the semiconductor package of the present invention prevents delamination of the adhesive layer and the semiconductor chip, and also reduces its size.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A printed circuit board comprising:
a body substrate;
a solder resist layer including an open portion that exposes a portion of the body substrate; and
an adhesive layer formed on the body substrate in the open portion.

2. The printed circuit board of claim 1, wherein the adhesive layer comprises one of a solid die attach film and a liquid adhesive, wherein the solder resist layer includes first and second ends adjacent to the open portion, and wherein the adhesive layer includes first and second ends adjacent to the first and second ends of the solder resist layer, respectively.

3. The printed circuit board of claim 2, wherein a width of the adhesive layer is less than a width of the open portion, such that the first and second ends of the adhesive layer are spaced apart from the first and second ends of the solder resist layer, respectively.

4. The printed circuit board of claim 2, wherein, edge open portions exposing the body substrate are formed at the first and second ends of the adhesive layer, such that delamination of the adhesive layer is structurally suppressed due to a locking effect caused by the edge open portions.

5. The printed circuit board of claim 1, further comprising a plurality of wiring patterns on a top surface of the body substrate and in the open portion.

6. The printed circuit board of claim 5, wherein the adhesive layer is formed on the wiring patterns and the body substrate in the open portion.

7. The printed circuit board of claim 5, wherein the wiring patterns are spaced apart from each other, wherein the adhesive layer is formed between the spaced apart wiring patterns and on the body substrate in the open portion, and wherein the adhesive layer and the wiring patterns are densely formed without voids.

8. The printed circuit board of claim 7, wherein the adhesive layer is entirely formed on the body substrate in the open portion and between the separated wiring patterns, such that delamination is structurally suppressed by a locking effect.

9. The printed circuit board of claim 1, wherein the open portion is formed on substantially a middle portion of the body substrate, and the solder resist layer is formed on the body substrate adjacent to and separate from the open portion.

10. The printed circuit board of claim 1, wherein the adhesive layer has a top surface higher than the solder resist layer, the top surface being substantially flat.

11. A semiconductor package comprising:
a printed circuit board including a body substrate, a solder resist layer, and an adhesive layer, the solder resist layer including an open portion that exposes a portion of the body substrate, the adhesive layer being formed on the body substrate in the open portion;
a semiconductor chip formed on the adhesive layer of the printed circuit board; and
an encapsulant structured to mold the printed circuit board and the semiconductor chip.

12. The semiconductor package of claim 11, wherein the adhesive layer comprises one of a solid die attach film and a liquid adhesive, wherein the solder resist layer includes first and second ends adjacent to the open portion, and wherein the adhesive layer includes first and second ends adjacent to the first and second ends of the solder resist layer, respectively

13. The semiconductor package of claim 12, wherein the adhesive layer has a width less than that of the open portion, and wherein edge open portions are formed on both the first and second ends of the adhesive layer, such that delamination of the adhesive layer and the semiconductor chip is structurally suppressed by a locking effect.

14. The semiconductor package of claim 11, wherein a width of the adhesive layer is configured to be different from a width of the semiconductor chip, such that delamination of the adhesive layer and the semiconductor chip is structurally suppressed by a locking effect.

15. The semiconductor package of claim 11, wherein a width of the adhesive layer is configured to be less than that of the semiconductor chip, such that delamination of the adhesive layer and the semiconductor chip is structurally suppressed by a locking effect.

16. The semiconductor package of claim 11, further comprising a plurality of wiring patterns on a top surface of the body substrate and in the open portion, and a solder ball attached to a bottom surface of the body substrate.

17. The semiconductor package of claim 16, wherein the adhesive layer is formed between the wiring patterns and on the body substrate in the open portion, such that delamination of the adhesive layer and the semiconductor chip is structurally suppressed by a locking effect.

18. A semiconductor package comprising:
a printed circuit board including a body substrate, a plurality of wiring patterns formed on the body substrate, a solder resist layer, and an adhesive layer, the solder resister layer including an open portion that exposes the body substrate and wiring patterns in a middle portion of the wiring patterns, the adhesive layer being spaced apart from one end of the solder resist layer in the open portion and being densely formed between the wiring patterns and on the body substrate without voids;
a semiconductor chip attached on the adhesive layer of the printed circuit board; and
an encapsulant structured to mold the printed circuit board and the semiconductor chip, thereby substantially covering the printed circuit board and the semiconductor chip with the encapsulant.

19. The semiconductor package of claim 18, wherein, when the adhesive layer is formed, edge open portions exposing the body substrate are respectively formed on both ends of the adhesive layer, such that delamination of the adhesive layer and the semiconductor chip is structurally suppressed due to a locking effect caused by the edge open portions.

20. The semiconductor package of claim 18, wherein a width of the adhesive layer is configured to be less than a width of the semiconductor chip, such that delamination of the adhesive layer and the semiconductor chip is structurally suppressed by a locking effect.
